(19) United States
(12) Patent Application Publication
(10) Pub. No.: US 2011/0174944 A1
(43) Pub. Date: Jul. 21, 2011

(54) RECESS VIDEO DISPLAY MOUNTING SYSTEM

(76) Inventor: Christopher S. Fredette, Advance, NC (US)

(21) Appl. No.: 13/008,719

(22) Filed: Jan. 18, 2011

Related U.S. Application Data
(60) Provisional application No. 61/295,433, filed on Jan. 15, 2010.

(51) Int. Cl. H05K 7/14

(52) U.S. Cl. 248/220.22

(57) ABSTRACT

Technologies are described herein for a recess video display mounting system. The recess video display mounting system may be fixed to the front frame of a recess or nook to support the load of a mounted video display. The recess video display mounting system can include a center plate upon which a video display may be mounted. Adjustable plates can extend from either side of the center plate to be fixed to the side framing of the recess or nook. One or more adapter plates may extend from the top and/or bottom of the center plate to be fixed to the horizontal framing at the top and/or bottom of the recess or nook. The recess video display mounting system can support newer, larger, flat-panel video displays.

### CROSS-REFERENCE TO RELATED APPLICATION

This application claims the benefit of U.S. provisional patent application No. 61/295,433, filed on Jan. 15, 2010, entitled “Nook Television Mount,” which is expressly incorporated herein by reference in its entirety.

### BACKGROUND

Video display systems may include televisions, monitors, computer monitors, electronic signs, or other systems for displaying video, images, photographs, advertisements, or any other visual information. Traditional, cathode ray tube (CRT), video displays are substantially cube-shaped. In contrast, modern video displays are generally flat screen configurations. Such modern display systems are typically based on plasma, liquid crystal display (LCD), light emitting diodes (LED), or other flat panel technology. Furthermore, modern display systems may have much larger front surfaces and have more elongated aspect ratios. Recesses, such as nooks in walls and furniture, once capable of, or intended for, housing CRT video displays may not be able to support modern flat screen video displays.

A traditional approach to use a recess for a modern video display is to build out the recess, for example constructing a frame of two-by-four wood studs. Such an approach essentially creates a front wall surface on, or within, the recess whereupon a flat panel display mount may be affixed. This framing operation can be very time consuming for installers. Also, the framing within the completed installation may be unattractive when viewed from various angles around the video display.

It is with respect to these considerations and others that the disclosure made herein is presented.

### SUMMARY

Technologies are described herein for a recess video display mounting system. The recess video display mounting system may be fixed to the front frame of any recess or nook to support the load of the mounted video display. The recess video display mounting system can include a center plate upon which a video display may be mounted. Adjustable plates can extend from either side of the center plate to be fixed to the side framing of the recess or nook. One or more adapter plates may extend from the top and/or bottom of the center plate to be fixed to the horizontal framing at the top and/or bottom of the recess.

The recess video display mounting system can support video displays much larger than the recess itself. The recess video display mounting system can support using space behind the mount and video display. For example, the recess space may support other audio/visual equipment while the mounting system is installed. The recess video display mounting system can support newer, larger displays. For example, a large flat panel television set with a 16:9 aspect ratio may be used in a recess originally intended to accommodate a smaller, traditional CRT television set with a 4:3 aspect ratios.

The recess video display mounting system can support video displays directly by interfacing mechanically with the back of the video display. Also, the recess video display mounting system can support video displays by interfacing mechanically with existing manufactured wall mounts. For example flat mounts, tilt mounts, cantilever mounts, motorized mounts, and so forth. The recess video display mounting system can be used in any recess, such as a nook, niche, armoire, cabinet, or other furniture or structure.

It should be appreciated that the above-described subject matter may also be implemented as an apparatus, a system, an installation process, a manufacturing process, or as an article of manufacture. These and various other features will be apparent from a reading of the following Detailed Description and a review of the associated drawings.

This Summary is provided to introduce a selection of concepts in a simplified form that are further described below in the Detailed Description. This Summary is not intended to identify key features or essential features of the claimed subject matter, nor is it intended that this Summary be used to limit the scope of the claimed subject matter. Furthermore, the claimed subject matter is not limited to implementations that solve any or all disadvantages noted in any part of this disclosure.

### BRIEF DESCRIPTION OF THE DRAWINGS

FIG. 1 is a schematic diagram illustrating a recess video display mounting system installed within a nook according to one or more embodiments presented herein;

FIG. 2 is an exploded schematic diagram illustrating a recess video display mounting system according to one or more embodiments presented herein;

FIG. 3A is a schematic diagram illustrating a recess video display mounting system with adjustment fasteners according to one or more embodiments presented herein;

FIG. 3B is a schematic diagram illustrating a recess video display mounting system with gripping interfaces between plates according to one or more embodiments presented herein;

FIG. 4 is a schematic diagram illustrating various installation configurations for a recess video display mounting system according to one or more embodiments presented herein;

FIG. 5 is a schematic diagram illustrating various reinforced installation configurations for a recess video display mounting system according to one or more embodiments presented herein;

FIG. 6 is a top view of a schematic diagram illustrating a recess video display mounting system according to one or more embodiments presented herein;

FIG. 7 is a schematic diagram illustrating a recess video display mounting system with attachable rails according to one or more embodiments presented herein; and

FIG. 8 is a side view of a schematic diagram illustrating a recess video display mounting system with latching rails according to one or more embodiments presented herein.

### DETAILED DESCRIPTION

The following description is directed to technologies for mounting a video display within a recess. Through the use of the embodiments presented herein, a recess video display mounting system can support video displays within a recess or nook either directly or by interfacing mechanically with existing manufactured television wall mounts. The recess video display mounting system can support flat, tilt, motorized, or cantilever configurations for supporting flat screen video displays from within a recess or nook.

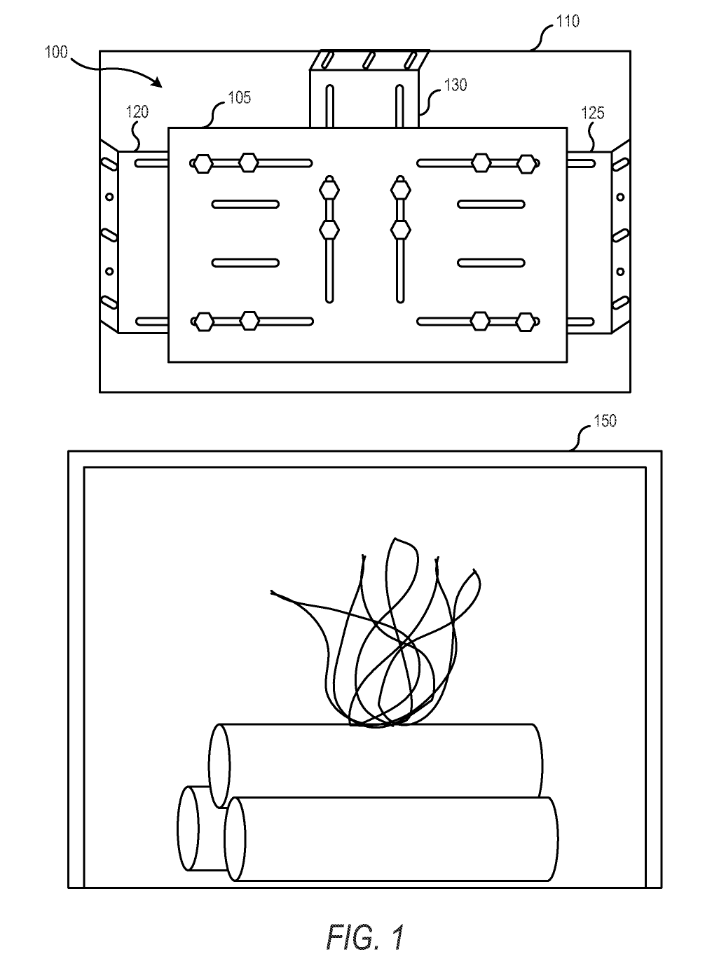

Turning now to FIG. 1, a schematic diagram illustrates a recess video display mounting system 100 installed within a recess 110 according to one or more embodiments presented herein. The recess video display mounting system 100 includes a center plate 105 upon which a video display may be mounted. Adjustable side plates 120, 125 can extend from either side of the center plate 105 to be fixed to the side framing of the recess 110. An adapter plate 130 can extend from the top of the center plate 105 to be fixed to top horizontal framing of the recess 110. The recess video display mounting system 100, including the center plate 105, the adjustable side plates 120, 125, and/or the adapter plates 130 may comprise metal, composites, or any other durable material capable of structurally supporting the weight of the mounted television set.

It should be appreciated that the recess 110 can be any void, opening, nook, niche, or other spacing within a wall, a piece of furniture, or any other video display installation site. According to some embodiments, a void above a fireplace 150 may be referred to as a fireplace nook or fireplace niche and may provide a recess to support installation of the recess video display mounting system 100. The recess video display mounting system 100 may also be used within existing furniture such as antiques, armoires, cabinetry, kitchen cabinets, entertainment centers, and so forth.

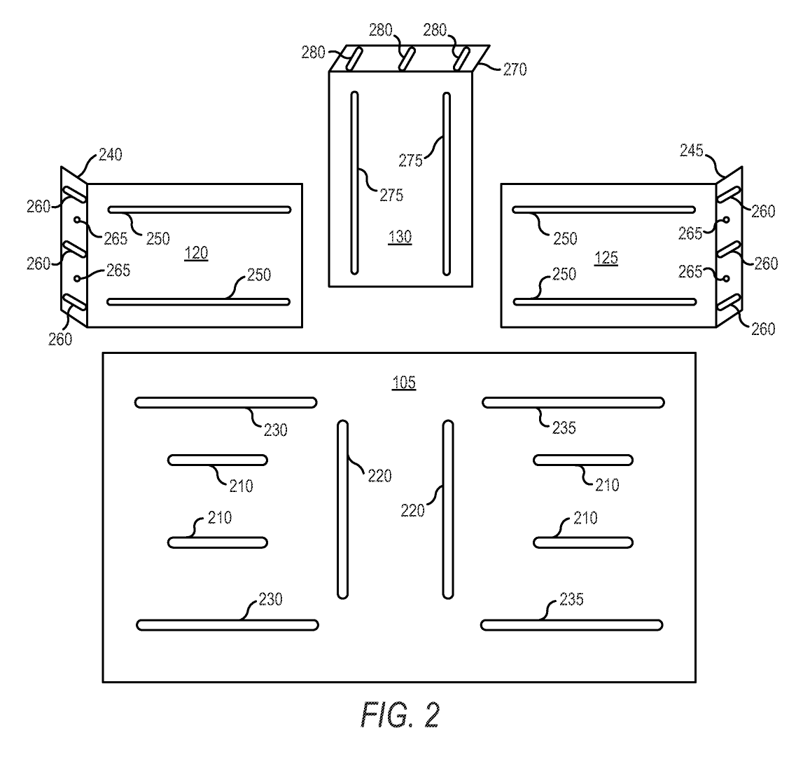

Turning now to FIG. 2, an exploded schematic diagram illustrates a recess video display mounting system 100 according to one or more embodiments presented herein. The center plate 105 can include video display mounting holes 210. The video display mounting holes 210 may be configured to accommodate hole space standards as specified by the Video Electronics Standards Association (VESA) for mounting directly to a video display such as a television set or video monitor.

Examples of video display mounting hole standards can include the Flat Display Mounting Interface (FDMI) and the VESA Mounting Interface Standard (MIS). Many of these standards specify four mounting screws arranged in a square with the vertical and horizontal distances between screw centers being 75 mm, 100 mm, 200 mm, 400 mm, or various other standard spacing distances. Some variants may specify rectangular screw hole patterns instead of square screw hole patterns.

The video display mounting holes 210 may be elongated and may be set in parallel, or alternatively in a star configuration, to accommodate televisions with mounting holes in various different positions. The video display mounting holes 210 may also support interfacing with any existing manufactured television mounts. Such existing mounts may include flat, tilt, cantilever bracket, or various other LCD/plasma video display mounts.

Side plate mounting holes 230,235 may be provided within the center plate 105. The side plate mounting holes 230, 235 can accommodate adjustable side plates 120, 125 extending from either side of the center plate 105. The side plate mounting holes 230, 235 may be slotted, or elongated, to allow the adjustable side plates 120, 125 to be adjusted in and out horizontally in relationship to the center plate 105. While illustrated as being two to each side of the center plate 105, the side plate mounting holes 230, 235 may be one, two, three, or any other number of holes, or slots, per side. The side plate mounting holes 230, 235 may also be a single slot all the way across the center plate 105 such that the mounting holes 230, 235 are a single hole. The number, location, or orientation of the side plate mounting holes 230, 235 is not limited and may take on any configuration without departing from the spirit or scope of the invention discussed herein.

Adapter plate mounting holes 220 may be provided within the center plate 105. The adapter plate mounting holes 220 can accommodate an adapter plate 130 extending from the top of the center plate 105. A second adapter plate 130 may also be affixed to the adapter plate mounting holes 220 to extend from the bottom of the center plate 105. The adapter plate mounting holes 220 may be slotted, or elongated, to allow one or more adapter plates 130 to be adjusted up and down vertically in relationship to the center plate 105.

The adjustable side plate 120 can include a main body and a mounting flange 240. Similarly, the adjustable side plate 125 can include a main body and a mounting flange 245. The flanges 240, 245 can provide an “L” shaped geometry to the main bodies of the adjustable side plates 120, 125. The mounting flanges 240, 245 can include slotted, or elongated, mounting holes 260 and/or secured mounting holes 265 for affixing the recess video display mounting system 100 into framing around or within the recess 110. The slotted, or elongated, mounting holes 260 may support bolts, screws, or other fasteners as needed in a flexible, positionable fashion to mechanically couple the recess video display mounting system 100 within framing around or within the recess 110. Once the recess video display mounting system 100 is positioned properly using slotted mounting holes 260, the secured mounting holes 265 may support additional secured anchoring of the recess video display mounting system 100 into the framing around or within the recess 110 using screws, bolts, or other fasteners.

The adjustable side plates 120, 125 may be mounted to the center plate 105 by positioning fasteners through both the side plate mounting holes 230, 235 within the center plate 105 and the corresponding mounting holes 250 within the adjustable side plates 120, 125. The side plate mounting holes 230, 235 and the corresponding mounting holes 250 may be slotted, or elongated, to allow for the adjustable side plates 120, 125 to be adjusted relative to the center plate 105. Such adjustment can position the adjustable side plates 120, 125 in and out horizontally to custom configure the total width of the recess video display mounting system 100 to match the inside width of the recess 110.

The adjustable side plates 120, 125 may be attached to the center plate 105 such that the mounting flanges 240, 245 of the adjustable side plates 120, 125 are directed forward in the direction of the video display, or backward into the recess 110. This flexibility, along with the slotted geometry of the side plate mounting holes 260 can support positioning the recess video display mounting system 100 as desired to accommodate the desired depth of the video display and the location of the framing or studs around or within the recess 110. Positioning the recess video display mounting system 100 relative to the framing or studs can increase the strength of coupling the recess video display mounting system 100 into the framing or studs using fasteners through mounting holes 260, 265 and thus increase the stability and weight bearing capacity of the recess video display mounting system 100.

Similar to the adjustable side plates 120, 125, the adapter plate 130 can include a mounting flange 270 providing the adapter plate 130 with an “L” shaped geometry. The mounting flange 270 can include slotted, or elongated, mounting holes 280 for affixing the recess video display mounting system 100 into framing around or within the recess 110. The adapter plate 130 may be mounted to the center plate 105 by positioning fasteners through both the adapter plate mounting holes 220 within the center plate 105 and the corresponding mounting holes 275 within the adapter plate 130. The corresponding mounting holes 275 may be slotted, or elongated, to allow for the adapter plate 130 to be adjusted relative to the center plate 105. Such adjustment can position the adapter plate 130 up and down vertically to custom configure the total height of the recess video display mounting system 100 to match the inside height of the recess 110. The adapter plate 130 may be attached to the center plate 105 such that the mounting flange 270 of the adapter plate is directed forward in the direction of the video display, or backward into the recess 110.

The use of an upper and/or lower adapter plate 130 can support mounting the recess video display mounting system 100 to a third or fourth stud or framing element of the recess 110 in addition to the two studs or framing elements of the recess 110 coupled to by the adjustable side plates 120, 125.

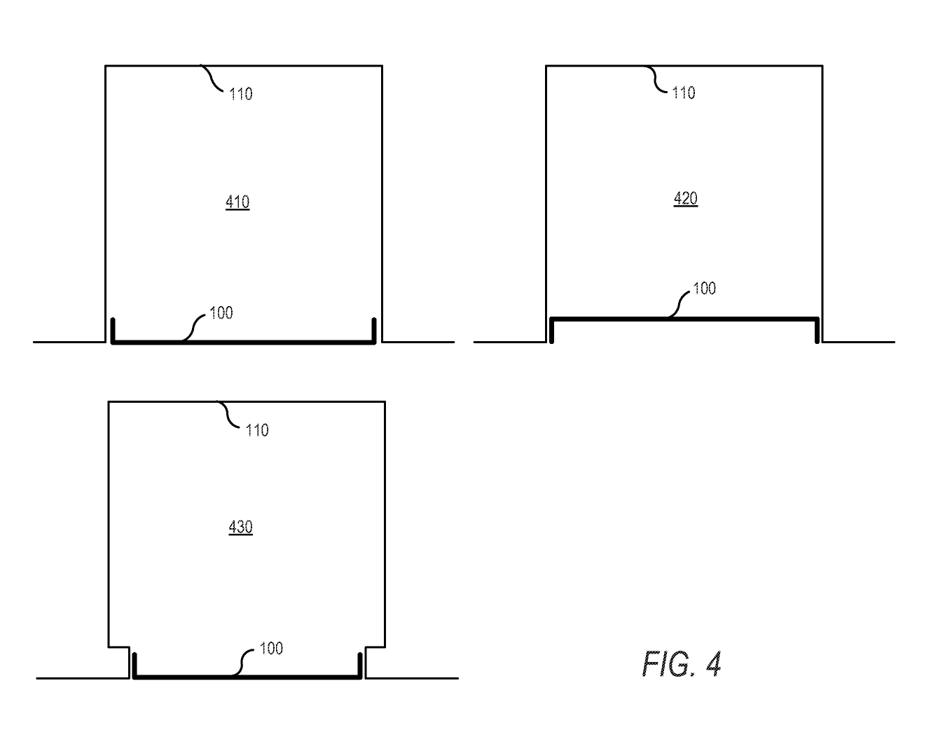

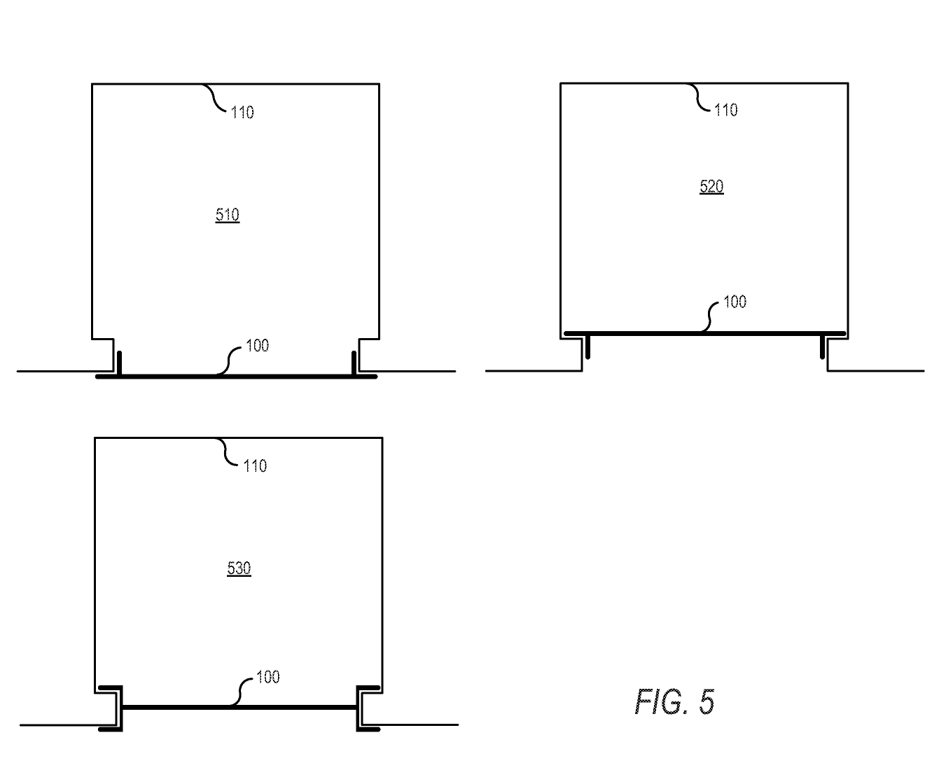

Additional flanges 240, 245, 270 may be provided on the adjustable side plates 120, 125 and/or the adapter plate 130 to double or triple reinforce the recess video display mounting system 100. This reinforcement may be accomplished by coupling recess video display mounting system 100 onto the studs or framing elements of the recess 110 using additional mated surfaces as discussed with respect to FIG. 4 and FIG. 5 below.

It should be appreciated that the “L” shaped geometry described above for the adjustable side plates 120, 125 and for the adapter plate 130 may also take on various other geometries to accommodate different shapes and configurations of recesses 110. The mounting flanges 240, 245, 270 may be positioned at approximate right angles (90 degree angles) to their respective plates in order to form “L” shaped geometries. Alternatively, the mounting flanges 240, 245, 270 may be positioned at various other angles to accommodate angled or sloped walls or trim within or around the recess 110. The angles of the mounting flanges 240, 245, 270 may be formed during manufacture. The angles may also be field modifiable. Field modification of the angles may involve bending of the mounting flanges 240, 245, 270. Also, the mounting flanges 240, 245, 270 may be coupled to their respective plates by one or more hinges, or locking hinges, to support various mounting angles.

The video display mounting system 100 may be painted, powder coated, or otherwise treated or coated. Each of the center plate 105, the adjustable side plates 120, 125, and the adapter plate 130 may be treated individually or differently. For example, the two adjustable side plates 120, 125 or the adapter plate 130 may be specifically painted or powder coated to have a color that matches or intentionally corresponds with the trim or walls within or around the recess 110. According to some embodiments, the adjustable side plates 120, 125 are powder coated white, grey, beige, or another neutral color to match the neutral colors of most residential or commercial walls where video displays are installed.

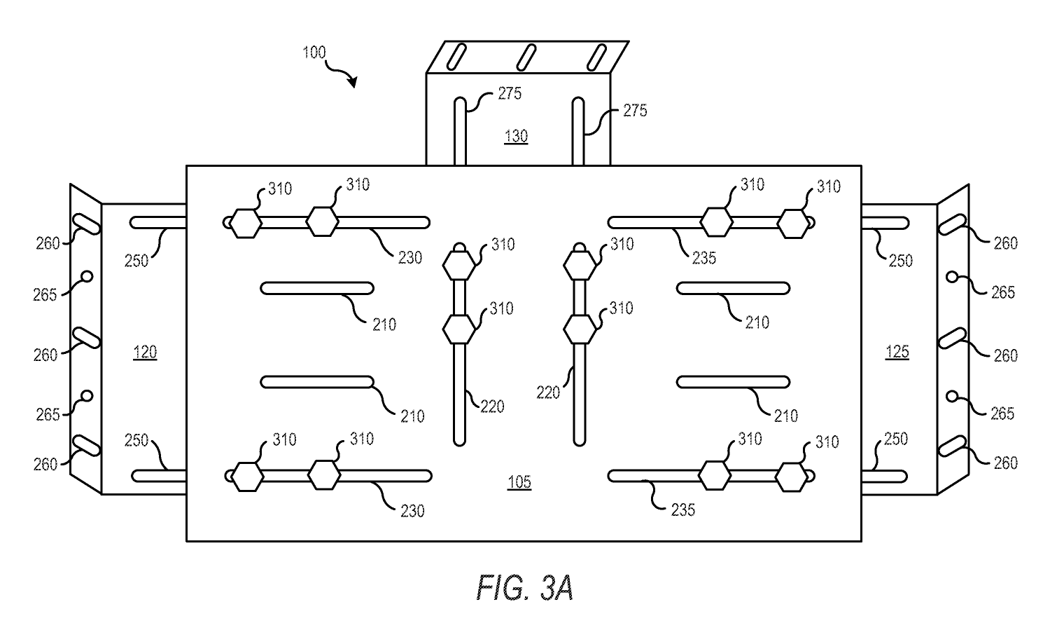

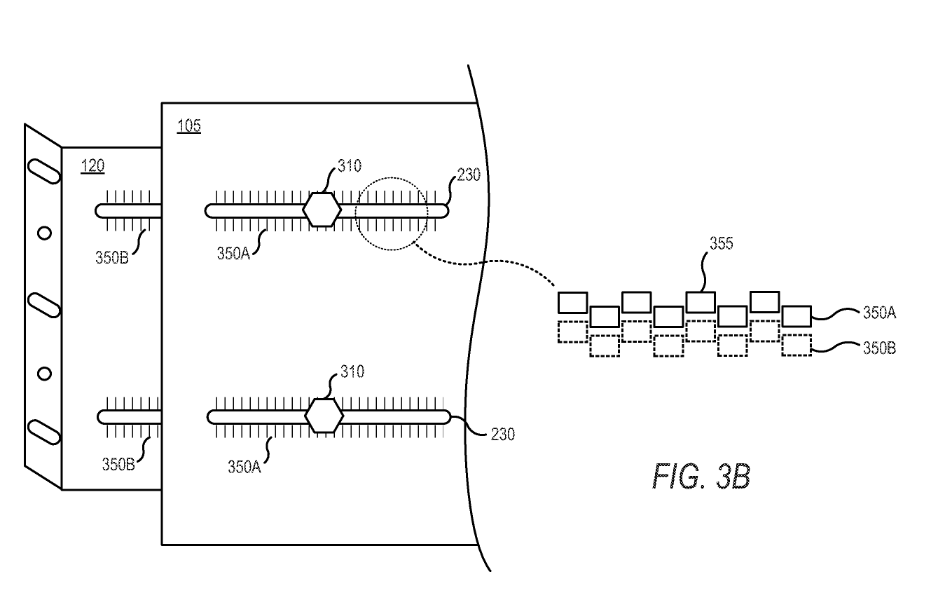

Turning now to FIG. 3A, a schematic diagram illustrates a recess video display mounting system 100 with adjustment fasteners 310 according to one or more embodiments presented herein. The adjustment fasteners 310 may be used to mount the adjustable side plates 120, 125 to the center plate 105 and/or to mount one or two adapter plates 130 to the center plate 105.

The adjustment fasteners 310 may be used to mount the adjustable side plates 120, 125 to the center plate 105 by positioning fasteners through both the side plate mounting holes 230, 235 within the center plate 105 and the corresponding mounting holes 250 within the adjustable side plates 120, 125. The adjustment fasteners 310 may also be used to mount one or two adapter plates 130 to the center plate 105 by positioning fasteners through both the adapter plate mounting holes 220 within the center plate 105 and the corresponding mounting holes 275 within the adapter plates 130.

The adjustment fasteners 310 may be nuts, bolts, clamps, cams, rivets, snaps, screws, ties, any other fastener, or any combination thereof.

Turning now to FIG. 3B, a schematic diagram illustrates a recess video display mounting system 100 with gripping interfaces 350A, 350B between plates according to one or more embodiments presented herein. The gripping interfaces 350A, 350B may be referred to collectively, or in general, as gripping interfaces 350. The gripping interfaces 350 may contact between the center plate 105 and the adjustable side plates 120, 125.

The gripping interfaces 350A may be positioned around the side plate mounting holes 230, 235 within the center plate 105. Another set of gripping interfaces 350B may be positioned around the mounting holes 250 within the adjustable side plates 120, 125. As the center plate 105 and the adjustable side plates 120, 125 are coupled using the adjustment fasteners 310, the gripping interfaces 350A and 350B may grip together to add stability to the recess video display mounting system 100. The added rigidity may support a reduction in the number of adjustment fasteners 310 used to couple the center plate 105 and the adjustable side plates 120, 125.

The gripping interfaces 350 may comprise interlocking teeth 355, other interdigitating elements, gripping textures, or frictional gripping surfaces. The gripping interfaces 350 may be formed by punching the interlocking teeth 355, punching other patterns or textures, cutting other patterns or textures, painting textures, knurling, powder coating textures, adhering gripping textures, adhering other gripping substances such as sand or rubber, applying or forming any gripping or frictional surface, or any combination of such techniques.

In addition to coupling between the center plate 105 and the adjustable side plates 120, 125, the gripping interfaces 350 may also couple between the center plate 105 and the adapter plate 130 extending from the top and/or the bottom of the center plate 105. It should be appreciated that in addition to being positioned adjacent to the mounting holes 220, 230, 235, 250, 275, the gripping interfaces 350 may also be positioned elsewhere on the center plate 105, the adjustable side plates 120, 125, and/or the adapter plate 130 such that mating plates together couples the gripping interfaces 350. Such coupling of the gripping interfaces 350 can support increased rigidity and stability to the assembled recess video display mounting system 100.

Turning now to FIG. 4, a schematic diagram illustrates various installation configurations for a recess video display mounting system 100 according to one or more embodiments presented herein. Three configurations 410, 420, 430 are presented, however it should be appreciated that other configurations may be used according to the technology disclosed herein.

Configuration 410 shows a plan view, or top-down view, of a recess video display mounting system 100 mounted into the opening of a recess 110. The recess video display mounting system 100 is configured such that mounting flanges 240, 245 of the adjustable side plates 120, 125 are directed inward towards the recess 110 and away from the video display.

Configuration 420 shows a plan view, or top-down view, of a recess video display mounting system 100 mounted into the opening of a recess 110. The recess video display mounting system 100 is configured such that mounting flanges 240, 245 of the adjustable side plates 120, 125 are directed outward away from the recess 110 and towards the video display.

Configuration 430 shows a plan view, or top-down view, of a recess video display mounting system 100 mounted into the opening of a recess 110. Configuration 430 is configured similarly to configuration 410, however the recess 110 in configuration 430 has a front surface, or framing associated therewith, extending into the recess 110.

Turning now to FIG. 5, a schematic diagram illustrates various reinforced installation configurations for a recess video display mounting system 100 according to one or more embodiments presented herein. Three configurations 510, 520, 530 are presented, however it should be appreciated that other configurations may be used according to the technology disclosed herein.

Configuration 510 shows a plan view, or top-down view, of a recess video display mounting system 100 mounted into the opening of a recess 110. Configuration 510 is configured similarly to configuration 430, however the recess video display mounting system 100 is double reinforced at its mounting points to the framing of the recess 110. As illustrated, an additional mounting flange (similar to mounting flanges 240, 245, 270) is provided on the adjustable side plates 120, 125 so as to extend outward along an outside surface of the recess 110. This additional mounting flange is in addition to the mounting flange of configuration 430 that extends inward along the framing of the recess 110. The mounting flanges may be used to affixing the recess video display mounting system 100 to the studs, or framing around, or within, the recess 110. Such reinforcement of additional mounting flanges can increase the strength of mechanical coupling between the recess video display mounting system 100 and the recess 110. This may increase the maximum weight of the video display supported by the recess video display mounting system 100.

Configuration 520 shows a plan view, or top-down view, of a recess video display mounting system 100 mounted into the opening of a recess 110. Configuration 520 is configured similarly to configuration 510, however the recess video display mounting system 100 is double reinforced to provide an additional mounting flange extending along an inside surface of the recess 110 instead of along an outside surface of the recess 110.

Configuration 530 shows a plan view, or top-down view, of a recess video display mounting system 100 mounted into the opening of a recess 110. Configuration 530 may be said to be triple reinforced and may be configured similarly to a combination of configurations 510 and 520. The triple reinforcement can provide additional mounting flanges extending both along an inside surface of the recess 110 and along an outside surface of the recess 110.

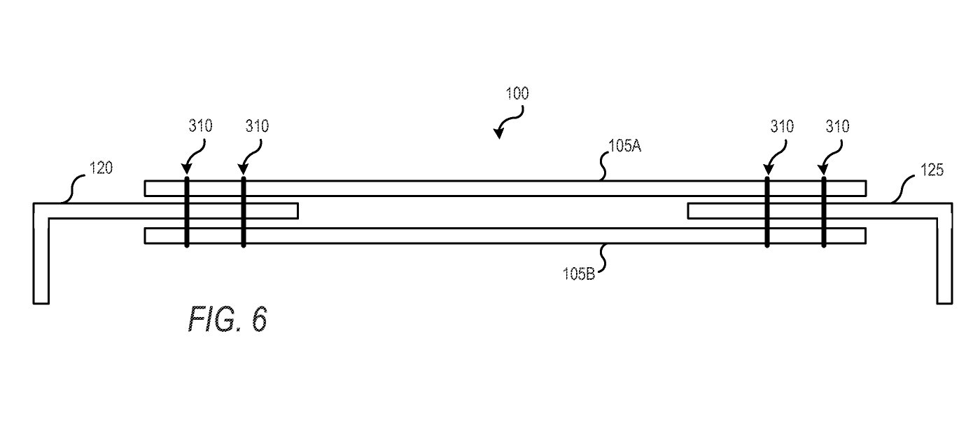

Turning now to FIG. 6, a top view of a schematic diagram illustrates a recess video display mounting system 100 according to one or more embodiments presented herein. Two identical, or similar, center plates 105A, 105B may be used together to increase the strength of the recess video display mounting system 100. The adjustable side plates 120, 125 and/or the adapter plates 130 may be sandwiched between the two center plates 105A, 105B. The two center plates 105A, 105B may be held together by fasteners 310 and/or gripping interfaces 350 as discussed above.

Sandwiching may reinforce the recess video display mounting system 100 to make it stronger and able to support larger video display units. Sandwiching may also support reduced thickness or weight of the materials needed to construct the recess video display mounting system 100.

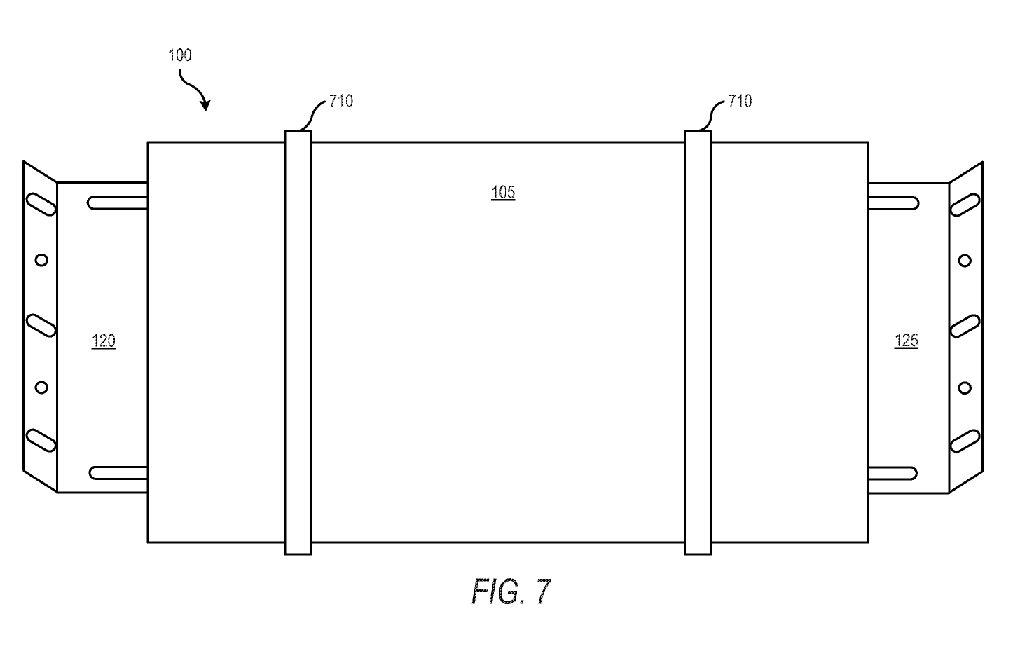

Turning now to FIG. 7, a schematic diagram illustrates recess video display mounting system 100 with attachable rails 710 according to one or more embodiments presented herein. The rails 710 may be attached to the video display to be mounted using screws, bolts, or other fasteners. The rails 710 may then be coupled to the center plate 105.

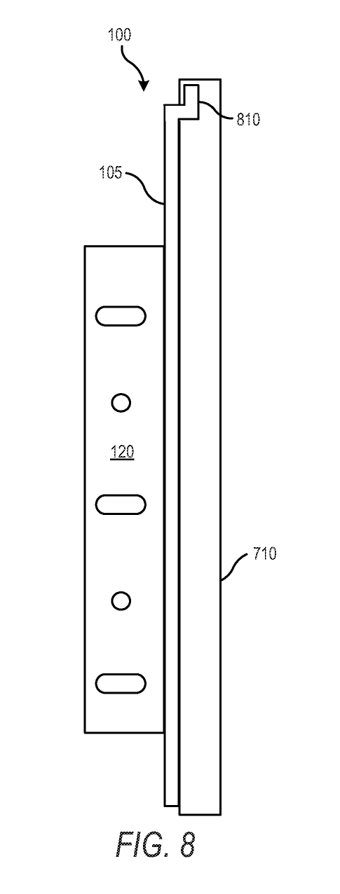

According to some embodiments, the rails 710 may be attached to the center plate 105 using any type of fastener. The rails 710 may be attached to the center plate 105 at video display mounting holes 210 or at any other mounting point. According to other embodiments, the rails 710 may connect to the center plate 105 by latching over the top of the center plate 105 as discussed in further detail with respect to FIG. 8. The rails 710 may be fixed, or the rails 710 may be rotatable to support the mounted television at an angle to the center plate 105. The rails 710 may also include locking mechanisms to support anti-theft security and/or earthquake safety. Such locking may also support safety during transit, in mobile application, accidental interference or any other mechanical interference.

Turning now to FIG. 8, a side view of a schematic diagram illustrates a recess video display mounting system 100 with latching rails 710 according to one or more embodiments presented herein. The rails 710 can be fixed to the rear of the video display to be mounted. The rails 710 may then latch into a ridge 810 along the top of the center plate 105. The rails 710 may also interface with a second ridge along the bottom of the center plate 105. The rails 701 may connect to the center plate 105 using a combination of latching ridge 810 and mechanical fasteners simultaneously for increased stability.

It should be appreciated that the technology discussed herein may include methods and processes for manufacturing the recess video display mounting system 100. For example, machines for forming, shaping, molding, stamping, forging, or machining metals or other materials may be used to transform raw materials into the recess video display mounting system 100 as disclosed herein.

The technology discussed herein may include methods and processes for assembling, configuring, and installing the recess video display mounting system 100. For example, a general purpose recess video display mounting system 100 may be transformed into a video display mount configured to mount a specific video display or television into a specific recess or nook according to operations related to the technology disclosed herein.

Based on the foregoing, it should be appreciated that technologies for recess video display mounting are presented herein. Although the subject matter presented herein has been described in specific language related to structural features or methodological acts, it is to be understood that the invention defined in the appended claims is not necessarily limited to the specific features or acts described herein. Rather, the specific features and acts are disclosed as example forms of implementation.

The subject matter described above is provided by way of illustration only and should not be construed as limiting. Various modifications and changes may be made to the subject matter described herein without following the example embodiments and applications illustrated and described, and without departing from the true spirit and scope of the present invention, which is set forth in the following claims.

What is claimed is:

1. A mounting system comprising:
a center plate configured to mechanically couple to a video display;
a right side plate comprising a first flange positioned distally from the center plate;
a left side plate comprising a second flange positioned distally from the center plate;
an adjustable right coupling between the center plate and the right side plate; and
an adjustable left coupling between the center plate and the right side plate, wherein the adjustable right coupling and the adjustable left coupling support adjusting a distance between the first flange and the second flange to correspond to a width associated with a recess within which the mounting system is installed.

2. The mounting system of claim 1, wherein the center plate comprises a standardized geometry of mounting holes to couple to the video display.

3. The mounting system of claim 1, wherein the center plate supports coupling to the video display using an angled video display mount.

4. The mounting system of claim 1, wherein the center plate supports coupling to the video display using a cantilevered video display mount.

5. The mounting system of claim 1, wherein the first flange and the second flange each comprise fastener holes supporting the mounting system being affixed to the recess.

6. The mounting system of claim 1, wherein the first flange extends at substantially a right angle from a body of the right side plate and the second flange extends at substantially a right angle from a body of the left side plate.

7. The mounting system of claim 1, wherein the right side plate comprises one or more hinges to support an adjustable angle between the first flange and a body of the right side plate; and the left side plate comprises one or more hinges to support an adjustable angle between the second flange and a body of the left side plate.

8. The mounting system of claim 1, further comprising an upper adapter plate or a lower adapter plate.

9. The mounting system of claim 1, wherein the adjustable right coupling comprises one or more slot-shaped mounting holes; and the adjustable left coupling comprises one or more slot-shaped mounting holes.

10. The mounting system of claim 1, wherein the adjustable right coupling comprises one or more fasteners; and the adjustable left coupling comprises one or more fasteners.

11. The mounting system of claim 1, wherein the adjustable right coupling comprises one or more gripping interfaces; and the adjustable left coupling comprises one or more gripping interfaces.

12. The mounting system of claim 1, wherein the right side plate and the left side plate each comprise a neutral coloring.

13. The mounting system of claim 1, wherein the recess comprises a nook above a fireplace.

14. The mounting system of claim 1, wherein the video display comprises a television.

15. The mounting system of claim 1, wherein the video display comprises a flat panel video display.

16. The mounting system of claim 1, wherein the video display comprises an outer geometry exceeding an outer geometry associated with the recess in one or more dimensions.

17. A mounting system comprising:
a center plate configured to mechanically couple to a video display;
a right side plate comprising a first set of flanges positioned distally from the center plate;
a left side plate comprising a second set of flanges positioned distally from the center plate;
an adjustable right coupling between the center plate and the right side plate; and
an adjustable left coupling between the center plate and the right side plate, wherein the adjustable right coupling and the adjustable left coupling support adjusting a distance between the one flange from the first set of flanges and one flange of the second set of flanges to correspond to a width associated with a recess within which the mounting system is installed.

18. The mounting system of claim 17, wherein two or more flanges of the first set of flanges are configured to be mechanically coupled to two or more surfaces associated with the recess.

19. The mounting system of claim 17, further comprising a second center plate configured to increase the capacity of the mounting system.

20. A mounting system comprising:
a center plate having a standardized geometry of mounting holes for mechanically coupling to a video display;
a right side plate comprising a first main body and a first flange positioned at a right angle from the first main body and distally from the center plate;
a left side plate comprising a second main body and a second flange positioned at a right angle from the second main body and distally from the center plate;
an adjustable right coupling between the center plate and the right side plate comprising one or more fasteners; and
an adjustable left coupling between the center plate and the right side plate comprising one or more fasteners, wherein the adjustable right coupling and the adjustable left coupling support adjusting a distance between the first flange and the second flange to correspond to a width associated with a recess within which the mounting system is installed.
